(19) United States
(12) Patent Application Publication
(10) Pub. No.: US 2010/0067289 A1
(43) Pub. Date: Mar. 18, 2010

(54) SEMICONDUCTOR DEVICE

(75) Inventor: Yukio FUJI, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: Elpida Menory, Inc., Tokyo (JP)

(21) Appl. No.: 12/557,194

(22) Filed: Sep. 10, 2009

(30) Foreign Application Priority Data
Sep. 12, 2008 (JP) 2008-234993

(51) Int. Cl. G11C 11/00; G11C 5/14; G11C 7/00

(52) U.S. Cl. 365/163; 365/226; 365/189.16; 365/189.15; 365/148

(57) ABSTRACT

A semiconductor device includes first and second phase-change memory elements (GST1 and GST2), each being programmed by a current supplied from a power supply (Vdd). A set voltage and a reset voltage supplied to a pair of complementary write bit lines (WBT and WBB) are applied respectively to gates of first and second driver transistors (WN1 and WN2) that drive the first and second phase-change memory elements via first and second write switches (WSN1 and WSN2) made conductive when a write word line is activated. The reset voltage and the set voltage are generated in a write circuit by voltage drop of predetermined voltage levels different each other from a boosted voltage (VPP) which is higher than the power supply voltage (Vdd).

### REFERENCE TO RELATED APPLICATION

This application is based upon and claims the benefit of the priority of Japanese patent application No. 2008-234993, filed on Sep. 12, 2008, the disclosure of which is incorporated herein in its entirety by reference thereto.

### BACKGROUND OF THE INVENTION

1. Field of the Invention

The present invention relates to a complementary phase-change memory cell.

2. Description of Related Art

Chalcogenide material such as Ge, Sb, and Te (hereinafter referred to as “GST”) has the property of being brought to an amorphous state (high resistance) or a crystalline state (low resistance) when heated, and thus such chalcogenide material is used in a phase-change memory.

FIG. 6 shows an example of the memory cell configuration of a phase-change memory. The memory cell comprises: a memory element (also referred to as “phase-change memory element”) GST having one end thereof connected to a bit line BL and made of phase-change material such as chalcogenide; and a select transistor (NMOS transistor) C1 connected between the other end of the memory element GST and a GND, having a gate supplied with a signal VG, and used to select 1 bit. The cell is selected when the select transistor C1 is conductive (on), and the cell is not selected when the select transistor C1 is non-conductive (off). It is known that chalcogenide has a phase-change property between an amorphous state and a crystalline state in the process of heating. Since the material exhibits low resistance in a crystalline state and high resistance in an amorphous state, the material is used as a memory element. Thus, GST is also referred to as a phase-change memory element. In FIG. 6, “VGST” beside the memory element GST designates the voltage across the terminals of the GST (applied voltage) and “Vds” designates a drain-to-source voltage of the NMOS transistor.

A programming of the phase-change memory will now be described. FIG. 7 shows a device characteristic (V-I characteristic) of a memory element GST in an amorphous state (hereinafter referred to as “reset state”). In case the memory element GST has a resistance Rrst in the reset state, if the voltage VGST applied to the memory element GST is gradually increased, upon reaching a certain voltage Vth (Max), the slope of the line indicating the resistance changes significantly. That is, a current according to a dynamic resistance Rdyn rapidly flows. This phenomenon is called OTS (Ovonic Threshold Switching). After the occurrence of OTS, when a current equal to or greater than a reset current value IReset is supplied, the GST is caused to be in an amorphous state and changed to a reset state. In contrast, when a current of a value between an Isafe and an Iset is supplied, the GST can be changed to a crystalline state (hereinafter referred to as “set state”).

IReset and the Isafe determine a margin between the reset programming current and the set programming current. The voltage VGST corresponding to the Isafe is defined as Vsafe. Further, the Vth varies depending on a temperature or phase state, and the minimum voltage at which the OTS occurs is defined as Vth (Min).

FIG. 8 shows current waveforms when data is written in a general phase-change memory. A horizontal axis is a program time, and a vertical axis is a temperature profile including current and resistor. Heat generated is calculated by the product of a resistance (R) and the square of a current (I) flowing through a resistance element such as an element, heater material and so forth.

A programming method will be described with reference to these current waveforms of FIG. 8. Assuming that the GST as a memory material is in a crystalline state, a temperature exceeding a melt temperature (Tm) is applied to the GST in a short time. The GST is then cooled in a short time. This is referred to as “Reset” and is a temperature profile in which the phase of the GST is changed from a crystalline state to an amorphous state.

To change the phase from an amorphous state to a crystalline state, the memory element GST needs to be provided with a pulse longer than the Reset at a temperature lower than Tm and then subjected to slow cooling. This is referred to as “Set”. It is possible to obtain at least one-digit difference between the set and reset resistance values.

Thus, since a large dynamic range in resistance can be obtained, even when the GST is used for large-capacity memory products, a sufficiently applicable operating margin can be obtained.

Generally, since the phase between a high resistance state (reset) and a low resistance state (set) is changed by Joule heat generated by current and application time, it is necessary that a large current flow through the memory element GST. For example, regarding the write current presented at the VSLI symposium, the ISSCC (International Solid-State Circuits Conference), or the like, the current required for the reset (from a crystalline state to an amorphous state) is reported to be approximately 400 uA (micro ampere) to 600 uA, and the current required for the set needs to be approximately 50% of the current required for the reset.

As described above, when storing data in the memory cell, different program currents need to be controlled and supplied with different pulse widths for the set and the reset, each other.

The speed (time) necessary for reset programming is 10 ns, and thus, the GST can be caused to be in an amorphous state at high speed. In contrast, the speed (time) necessary for set programming is ten times or greater than the speed required for reset programming, and thus the GST requires more time to be in a crystalline state.

Further, there is dependence of the speed (time) required for the set programming, on a set resistance value, and a distribution characteristic of set resistance values. Non-Patent Document 1 discloses an example of such dependence.

Next, the relationship between the crystallization speed and the distribution characteristic of the set resistance values will be described with reference to FIG. 9. FIG. 9 shows the reset resistance (Rreset) distribution characteristics when the reset programming is executed and also shows dependence of the set resistance (Rset) distribution on a set programming speed (tSET) when the set programming is executed.

Referring to FIG. 9, when the set programming speed (tSET) indicated by the solid line is 200 ns, the resistance margin (indicated by arrows in the figure) between the minimum value of the reset resistance (Rreset) and the maximum value of the set resistance (Rset) shows approximately one digit difference in resistance.

The dashed line designates the set resistance (Rset) distribution characteristics when the tSET is 100 ns, and the heavy solid line designates the set resistance (Rset) distribution characteristics when the tSET is further increased to 50 ns.

As the set programming speed (tSET) becomes faster, the width of the resistance value distribution increases, and accordingly, the margin between the minimum value of the Rreset and the maximum value of the Rset decreases.

It is thought that this is because variation of select transistors or GSTs inhibits the progress of crystallization from the high-resistance reset state, that is, from the amorphous state, through sufficient current, heat generation, and slow cooling, and as a result, a perfect crystalline state cannot be reached.

Thus, when the set is executed at high speed, one-digit difference in resistance or more cannot be obtained between the high-resistance reset state and the set state. If variations of memory cells are taken into account, read operation may not be executed properly.

In addition, as shown in FIG. 9, when the set programming is executed at high speed, the set resistance (Rset) is widely distributed in the higher resistance range. Thus, when comparison and detection are made by using a reference cell voltage which is commonly used in a general nonvolatile memory, since a time constant is increased based on a written resistance R and a bit-line capacitance C (t=CR), the sense time required for detecting the difference from the decision voltage (reference cell voltage) is increased by 50%.

Next, a program current will be described. FIG. 10 shows a relationship between a write circuit (write amplifier) and a memory cell in a phase-change memory circuit and a relationship between the voltages applied. The memory cell comprises a GST and a NMOS transistor C1 that are shown in FIG. 6 and connected in series between the bit line BL and the GND. The write amplifier (Write Amp) comprises: a PMOS transistor P1 having a source connected to a program power supply Vprog and a gate supplied with a program pulse signal PProg, and a PMOS transistor P2 having a source connected to a drain of the PMOS transistor P1, a gate supplied with a reference voltage (bias voltage) Vref, and a drain connected to the bit line BL. The “Rbit” denotes a resistance component of the bit line BL.

The voltage necessary for supplying a current to the memory element GST is given by the following expression:

Vprog=Vds+Vh+(Ireset*Rdyn)+Vdrop

The parameter Rdyn, Vh (hold voltage), and reset current Ireset prescribed by the GST device basic parameters (FIG. 7) form the VGST.

The Vdrop is a voltage drop due to transistors and parasitic resistance in the write amplifier, Y-switch (not shown) transistor resistance, bit-line parasitic resistance (Rbit), and so forth, caused when supplying a voltage from the write amplifier to the drain of the actual memory cell.

In FIG. 10, when Vds=1 V, Vh=0.6 V, Rdyn=2 KΩ, Vdorp=1.5 V, and program current Iprog=300 uA, the necessary program voltage Vprog is 3.7 V.

Currently, a power supply voltage of a memory is lowered from 1.8 V to 1.2 V to reduce a memory system voltage.

Thus, in order to supply a voltage of 3.7 V, it is necessary to arrange an internal voltage-boost circuit in the memory circuit to supply the high voltage. In order to obtain such a voltage, the voltage Vprog is generated from a power supply voltage by a charge pump circuit or the like. The current efficiency which represents the relation between a circuit current necessary for the generation of the high voltage and an actual supply current is approximately 25% to 30%.

When simultaneous programming of 128-bits memory cells is performed with Iprog=300 uA, the entire program current is 38.4 mA. If the current efficiency is 25%, current consumption with respect to the memory system is 153 mA. The current efficiency could be even lower when a lower voltage is used.

Thus, since the program current is supplied from the boosted Vprog, current consumption of the memory system becomes enormous.

Patent Document 1 discloses an example of a complementary memory configuration in which a phase-change memory element is used as an OTP memory cell. In Patent Document 1, a current flowing through a write circuit (522T and 522C in FIG. 7 of Patent Document 1) is supplied to a GST to execute writing. This method is the same as the write circuit of FIG. 10. Further, while Patent Document 1 discloses a memory cell comprising a variable resistance element GST and a select transistor MT, this type of memory cell was known at the time of filing of Patent Document 1.

Further, regarding a read method, for example, Patent Document 2 discloses a MRAM (Magnetic Random Access Memory) using a complementary memory cell. In Patent Document 2, a current flows from a sense amplifier in a current path in which the sense amplifier and a memory cell are connected in series. The current flowing through the sense amplifier is directly supplied to the memory cell, and a latch circuit is inverted (the configuration of Patent Document 2 and that of the present invention are compared later).

Patent Document 1:

Japanese Patent Kokai Publication No. JP2007-164971A (pp. 18 to 20, FIG. 7)

Patent Document 2:

Japanese Patent Kokai Publication No. JP2005-166170A Non-Patent Document 1:

A 0.1 um 1.8V 256 Mb Phase-Change Random Access Memory with 66 MHz Synchronous Burst Read Operation: IEEE Journal of Solid-State Circuits Vol. 42. No. 1 Jan. 2007

### SUMMARY

Analysis will be hereinafter made based on the present invention.

There are two problems to be solved to realize a high-speed nonvolatile memory.

1) Program Pulse Width

A shortened program pulse and a uniformed pulse width for set and reset programming are demanded for higher speed operation. When the pulse width of set programming is made the same that of reset programming, a large dynamic range of the set and reset resistance cannot be obtained by a current value alone. Thus, there is a high possibility that the read margin is narrowed and high-speed access cannot be executed.

2) Program Current

Based on the configuration of FIG. 10, the current needs to be supplied through a bit line BL via a GST. When resistance of the bit line and resistance of the write amplifier are taken into account, a high voltage is needed, and thus, a boosted voltage Vpp is normally used. However, since the voltage Vpp is generated by an internal voltage-boost circuit, when the voltage is doubled by the voltage-boost circuit, the current efficiency is generally 25% to 30%. Thus, with respect to the memory system, the current required for writing data would be three to four times greater.

According to the present invention, there is provided a semiconductor device including a complementary memory cell comprising a pair of phase-change memory elements arranged between a power supply and a pair of outputs of a pair of driver transistors. When data is written, depending on a data value, one of the pair of driver transistors is driven by a reset voltage and the other driver transistor is driven by a set voltage, and a reset current is caused to flow through one of the pair of phase-change memory elements and a set current is caused to flow through the other phase-change memory element from the power supply. In the present invention, the reset voltage and the set voltage are generated in a write circuit by dropping predetermined levels from a boosted voltage higher than the power supply voltage. The set voltage and the reset voltage outputted from the write circuit to a pair of complementary write bit lines are applied to gates of the pair of driver transistors via a pair of write switches which are made conductive when a write word line is activated.

The present invention can contribute to a reduction of current consumption and an improvement of operating margin during writing.

Still other features and advantages of the present invention will become readily apparent to those skilled in this art from the following detailed description in conjunction with the accompanying drawings wherein only exemplary embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 shows an example of the configuration of a memory cell according to an exemplary embodiment of the present invention.

FIG. 2 shows an example of the configuration of a write circuit according to an exemplary embodiment of the present invention.

FIG. 3 shows an example of the configuration of a read circuit according to an exemplary embodiment of the present invention.

FIG. 4 shows a timing diagram illustrating a write operation according to an exemplary embodiment of the present invention.

FIGS. 5A and 5B show timing diagrams illustrating a read operation according to an exemplary embodiment of the present invention.

FIG. 6 shows an example of the configuration of a phase-change memory cell.

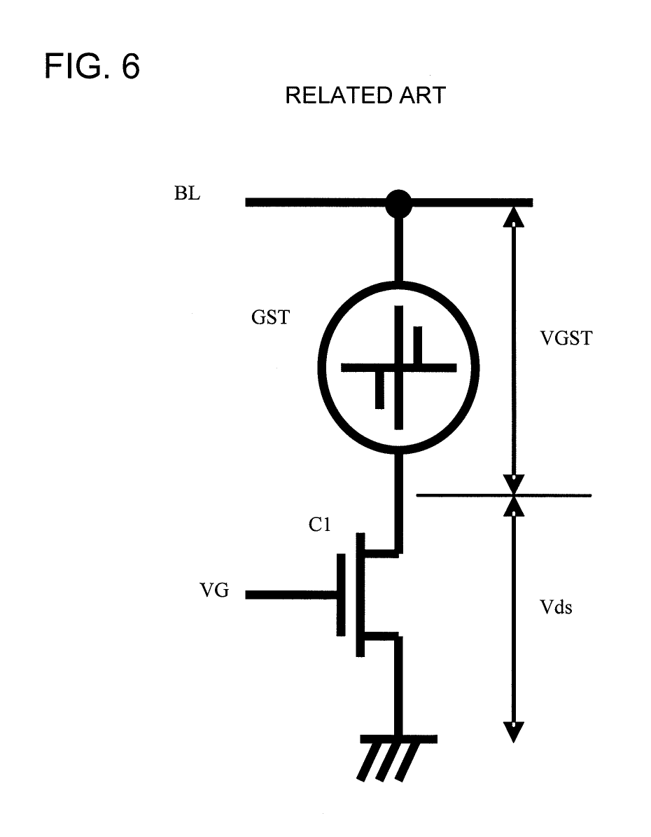

FIG. 7 shows characteristics of a GST device in an amorphous state (hereinafter referred to as “reset state”).

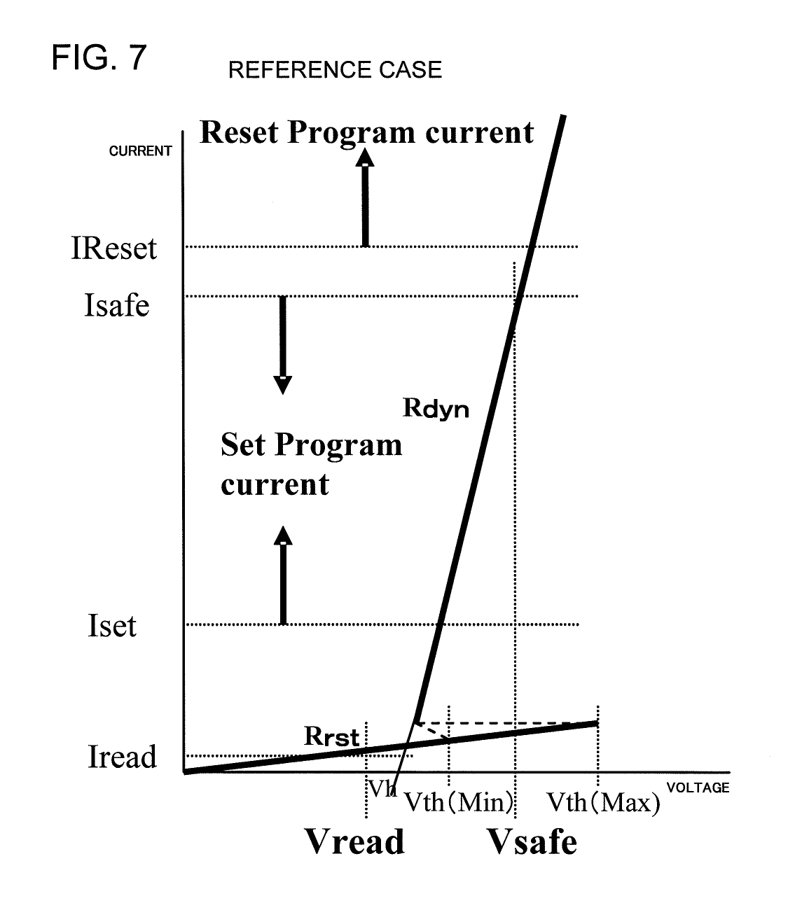

FIG. 8 shows current waveforms when data is written in a phase-change memory.

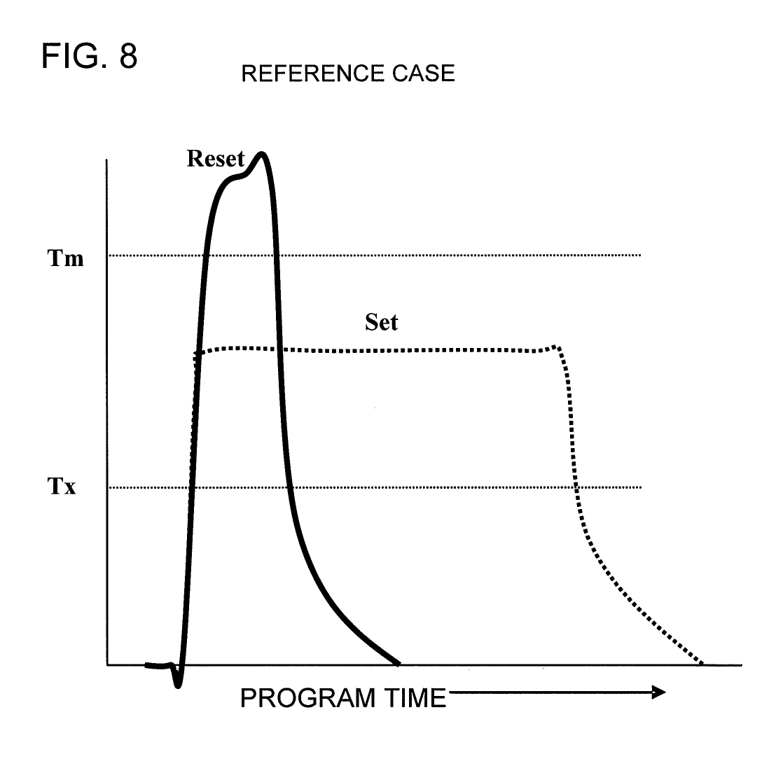

FIG. 9 shows reset resistance distribution characteristics when a reset programming is executed and dependence of the set resistance distribution on the set speed when a set programming is executed.

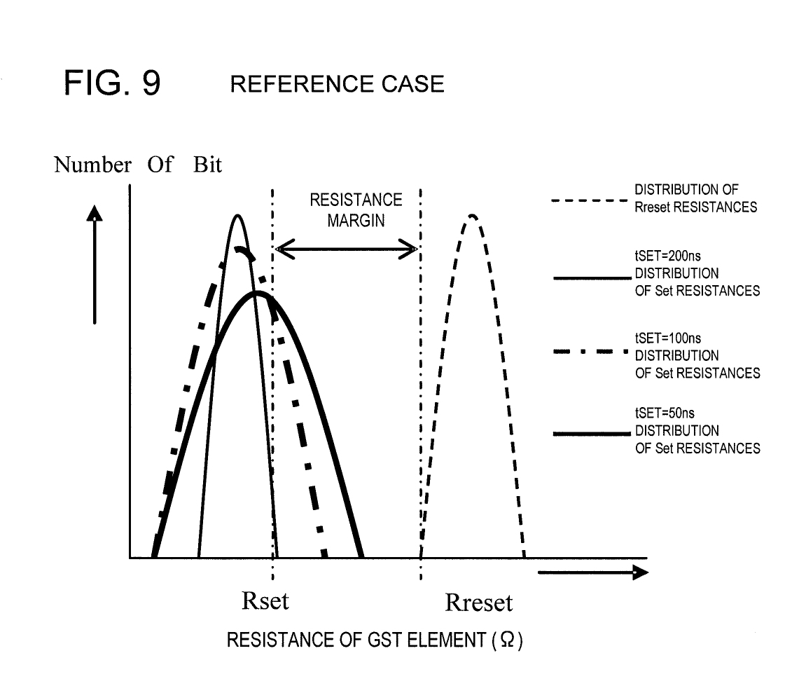

FIG. 10 shows a relationship between a write circuit (write amplifier) and a memory cell in a phase-change memory circuit and a relationship between the voltages applied.

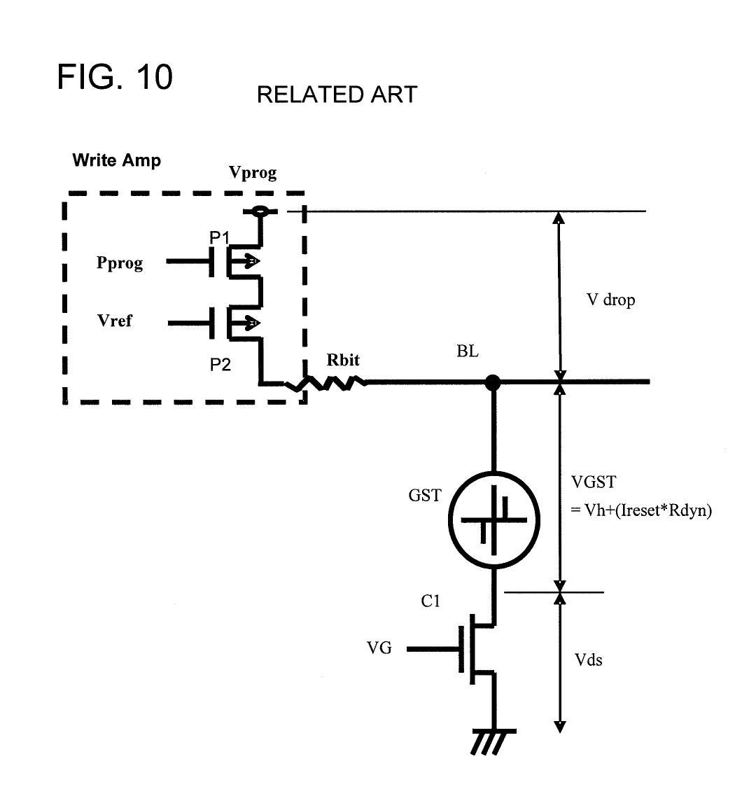

### PREFERRED MODES

In the present invention, a semiconductor device includes a memory cell comprises first and second phase-change memory elements (GST1 and GST2) between a power supply (Vdd) and first and second driver transistors (WN1 and WN2). In writing data, one of the first and second driver transistors (WN1 and WN2) is driven by a reset voltage and the other driver transistor is driven by a set voltage in accordance with a value of write data. A reset current is caused to flow through one of the first and second phase-change memory elements (GST1 and GST2) and a set current is caused to flow through the other phase-change memory element from the power supply (Vdd). The reset voltage and the set voltage are generated in a write circuit by voltage drop of predetermined voltage levels different each other, from a boosted voltage (VPP) which is higher than the power supply voltage (Vdd). The set voltage and the reset voltage supplied from the write circuit to a pair of complementary write bit lines (WBT and WBB) are applied respectively to gates of the first and second driver transistors (WN1 and WN2) via first and second write switches (WSN1 and WSN2) which are made conductive when a write word line (WWL) is activated. The currents are caused to flow through the first and second phase-change memory elements (GST1 and GST2) from the power supply (Vdd) so that one of the first and second phase-change memory elements (GST1 and GST2) is programmed to be in a reset state and the other is programmed to be in a set state.

In the present invention, the memory cell further comprises:

a first select transistor (WP1) having a gate supplied with a selection signal (XBS);

a first phase-change memory element (GST1); and

a first driver transistor (WN1), all of which are connected in series between a power supply (Vdd) and a ground (GND). Also, the memory cell comprises:

a second select transistor (WP2) having a gate supplied with the selection signal (XBS);

a second phase-change memory element (GST2); and

a second driver transistor (WN2), all of which are connected in series between the power supply (Vdd) and the ground (GND). The memory cell further comprises:

a first write switch (WSN1) which is arranged between a gate of the first driver transistor (WN1) and a first write bit line (WBT) of a complementary write bit line pair (WBT and WBB) and which is controlled to be made conductive/non-conductive by a write word line (WWL);

a first read switch (RN1) which is arranged between a connection node of the first phase-change memory element (GST1) and the first driver transistor (WN1) and a first read bit line (RBT) of a complementary read bit line pair (RBT and RBB) and which is controlled to be made conductive/non-conductive by a read word line (RWL);

a second write switch (WSN2) which is arranged between a gate of the second driver transistor (WN2) and a second write bit line (WBB) of the complementary write bit line pair (WBT and WBB) and which is controlled to be made conductive/non-conductive by the write word line (WWL); and

a second read switch (RN2) which is arranged between a connection node of the second phase-change memory element (GST2) and the second driver transistor (WN2) and a second read bit line (RBB) of the complementary read bit line pair (RBT and RBB) and which is controlled to be made conductive/non-conductive by the read word line (RWL).

In the present invention, there is provided a write circuit supplying set and reset voltages, which are complementary write voltages, to the complementary write bit line pair (WBT and WBB). The write circuit supplies the set voltage and the reset voltage in the same period in accordance with a value of write data. The write circuit obtains voltages which undergo voltage drop of certain levels from a boosted voltage (VPP) to supply the resulting voltages as the set voltage and the reset voltage to the complementary write bit line pair (WBT and WBB).

According to the present invention, the write circuit comprises:

a first reset voltage supply circuit that comprises first and second transistors (RTP1 and RTP2) connected in series between the boosted voltage (Vpp: high potential) and the write bit line true (WBT); and

a first set voltage supply circuit that comprises first, second, and third transistors (STP1, STP2, and STP3) connected in series between the boosted voltage (Vpp) and the first write bit line (WBT). A data signal (Din) and an inverted signal thereof are supplied to gates of the first transistors (RTP1 and STP1) of the first reset voltage supply circuit and the first set voltage supply circuit, respectively. A program pulse signal (PProg) is commonly supplied to gates of the second transistors (RTP2 and STP2) of the first reset voltage supply circuit and the first set voltage supply circuit. A predetermined bias voltage (VSetRef) is applied to a gate of the third transistor (STP3) of the first set voltage supply circuit. The write circuit further comprises: a second reset voltage supply circuit that comprises first and second transistors (RBP1 and RBP2) connected in series between the boosted voltage (Vpp) and the second write bit line (WBB); and a second set voltage supply circuit that comprises first, second, and third transistors (SBP1, SBP2, and SBP3) connected in series between the boosted voltage (Vpp) and the second write bit line (WBB). The inverted signal of the data signal (Din) and the data signal (Din) are supplied to gates of the first transistors (RBP1 and SBP1) of the second reset voltage supply circuit and the second set voltage supply circuit, respectively. The program pulse signal (PProg) is commonly supplied to gates of the second transistors (RBP2 and SBP2) of the second reset voltage supply circuit and the second set voltage supply circuit. The predetermined bias voltage (VSetRef) is applied to a gate of the third transistor (SBP3) of the second set voltage supply circuit. According to the present invention, there are also provided first and second discharging transistors (DN1 and DN2), through which currents flow when the program pulse signal (PProg) is not activated. The first discharging transistor (DN1) is arranged between the write bit line true (WBT) and the ground, and the second discharging transistor (DN2) is arranged between the write bit line bar (WBB) and the ground. With the write circuit as configured above, the set and reset voltages based on the program pulse signal (PProg) are supplied in the same time period. In accordance with a value of the data (Din), a voltage that undergoes a voltage drop of 2×Vtp from the boosted voltage (Vpp), where Vtp is a threshold voltage, is applied to one of the pair of complementary write bit lines (WBT and WBB) as the reset voltage, while a voltage that undergoes a voltage drop of 2×Vtp and also a voltage drop at the transistor (STP3 or SBP3) which is biased by the VSetRef, from the boosted voltage (Vpp) is applied to the other complementary write bit line as the set voltage. Thus, the reset and set voltages are applied to gates of the first and second driver transistors (WN1 and WN2) of a selected cell which is connected to the write word line (WWL) activated and which has switches (WSN1 and WSN2) made conductive.

In the present invention, there is provided a read circuit comprising: a pair of Y switches (YSWT and YSWB) connected to a complementary read bit line pair (including a first read bit line and a second read bit line) and commonly made conductive/non-conductive by a column selection signal; an equalization transistor (EQTr) arranged between the first and second read bit lines of the complementary read bit line pair and electrically connecting the read bit line par when an equalization signal is activated; a pair of transistors (SBT and SBB) arranged between the pair of Y switches and the ground and made conductive/non-conductive by a control signal; and a sense amplifier (SA) to which potentials of the complementary read bit line pair (RBT and RBB) are differentially supplied via the Y switches (YSWT and YSWB).

According to the present invention,

the set- and reset-pulse width is uniform:

instead of a single memory cell structure, a complementary memory cell structure is adopted;

programming the GST is carried out with a current supplied from the power supply Vdd; and

the boosted voltage (Vpp) is used only to control a voltage of a write word line.

The present invention will be hereinafter described in detail based on exemplary embodiments.

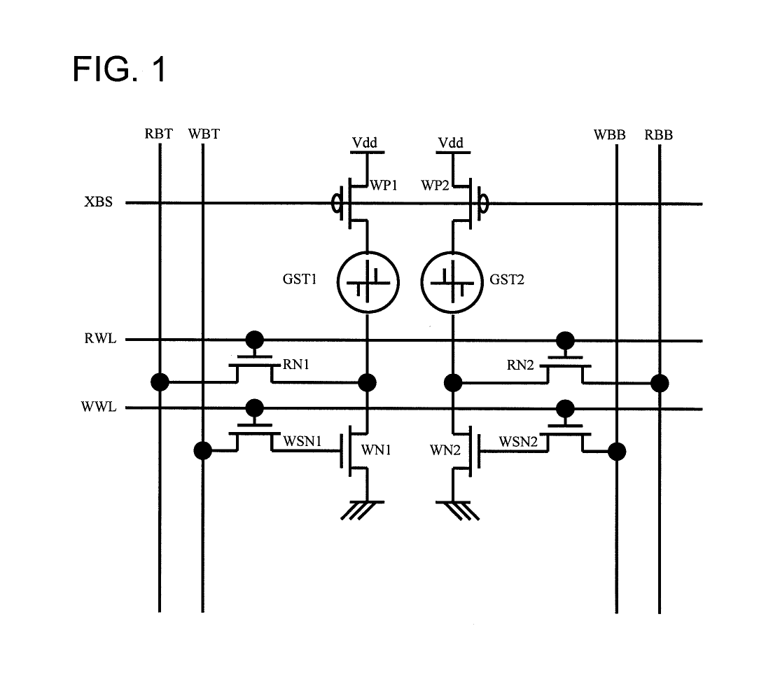

FIG. 1 shows an example of the circuit configuration of a complementary memory cell according to an exemplary embodiment of the present invention. Referring to FIG. 1, the memory cell according to the present exemplary embodiment comprises PMOS transistors WP1 and WP2, a chalcogenide elements GST1 and GST2, NMOS transistors RN1 and RN2, NMOS transistors WN1 and WN2 and NMOS transistors WSN1 and WSN2. The PMOS transistor WP1 has a source connected to a power supply Vdd and a gate connected to a block selection signal XBS. The chalcogenide element GST1 has one end thereof connected to a drain of the PMOS transistor WP1. The NMOS transistor RN1 is connected between the other end of the chalcogenide element GST1 and a read bit line true RBT and has a gate connected to a read word line RWL. The NMOS transistor WN1 has a drain connected to the other end of the GST1 and a source connected to the GND. The NMOS transistor WSN1 is connected between a gate of the NMOS transistor WN1 and a write bit line true WBT and has a gate connected to a write word line WWL.

The PMOS transistor WP2 has a source connected to the power supply Vdd and a gate connected to the block selection signal XBS. The chalcogenide element GST2 has one end thereof connected to a drain of the PMOS transistor WP2. The NMOS transistor RN2 is connected between the other end of the chalcogenide element GST2 and a read bit line bar RBB and has a gate connected the read word line RWL. The NMOS transistor WN2 has a drain connected to the other end of the chalcogenide element GST2 and a source connected to the GND. The NMOS transistor WSN2 is connected between a gate of the NMOS transistor WN2 and a write bit line WBB, and has a gate connected to the write word line WWL.

The write bit line bar WBB and the read bit line bar RBB are signal wirings having an inverted logic with respect to the write bit line true WBT and the read bit line true RBT, respectively, and these wirings comprise a complementary memory cell. The block selection signal XBS controls selection of memory cells on a block basis, each block comprising a plurality of memory cells. The last letter “T” as in WBT and RBT signifies “True” (non-inverting) and the last letter “B” as in the WBB and RBB signifies “Bar” (inverting).

In FIG. 1, when data is written in the memory cell, in order to select a memory cell, the block selection signal XBS is set to a low level and the chalcogenide elements GST1 and GST2 are provided with a Vdd level via the PMOS transistors WP1 and WP2 which are made conductive.

The read word line RWL is set to a low level, the transistors RN1 and RN2 are made non-conductive, and the signal transmission paths of the read bit line pair RBT and RBB are cut off.

The write word line WWL is set to a high level, and the transistors WSN1 and WSN2 are made conductive. Thus, signal levels of the write bit line pair WBT and WBB can be transferred to the driver transistors WN1 and WN2. Voltages applied to gates of the driver transistors WN1 and WN2 are controlled respectively in accordance with voltage levels of the write bit line pair WBT and WBB and voltages via the transistors WSN1 and WSN2 which have one electrodes connected to the gates of the driver transistors WN1 and WNS2 and other electrodes connected to the write bit line pair WBT and WBB, respectively. In accordance with current capability of the driver transistor WN1 (WN2), a current flows from the power supply Vdd via the chalcogenide element GST1 (GST2). Depending on the values of currents flowing through the chalcogenide elements GST1 and GST2 GST1 and GST2 undergo changes in heat generation states, as a result of which data can be written in the memory cell.

On the other hand, when data is read from the memory cell, the write word line WWL is set to a low level to disconnect an input path via the write bit lines WBT and WBB. The read word line RWL is set to a high level, and the transistors RN1 and RN2 are made conductive. Currents in accordance with resistance values of the chalcogenide elements GST1 and GST2 obtained by the phase change made by currents from the power supply Vdd in writing are caused to flow via the transistors RN1 and RN2 to the read bits line pair (RBT and RBB), whereby a voltage difference is generated between the read bit line pair (RBT and RBB).

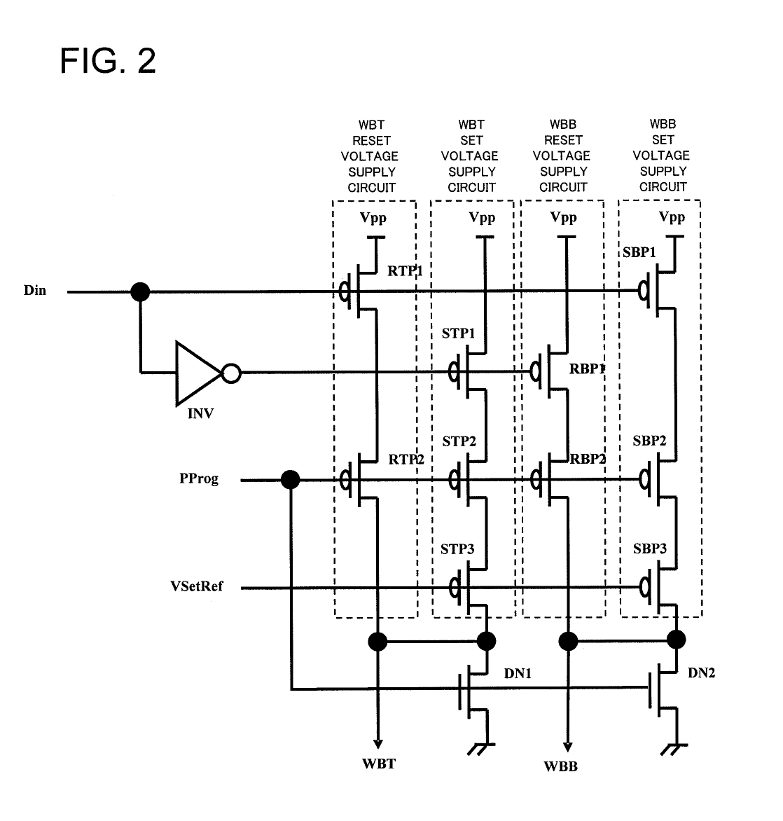

FIG. 2 shows an example of the configuration of a write control circuit according to the present exemplary embodiment. In FIG. 2, the write bit lines WBB and WBT are connected to the circuits described below to be provided with write potentials.

The write bit line true WBT is connected to a WBT reset voltage supply unit that comprises PMOS transistors RTP1 and RTP2 and a WBT set voltage supply unit that comprises PMOS transistors STP1 to STP3. More specifically, the WBT reset voltage supply unit comprises: a PMOS transistor RTP1 having a source connected to a boosted power supply Vpp and a gate supplied with a storage data value Din; and

a PMOS transistor RTP2 having a source connected to a drain of the RTP1, a gate supplied with a program pulse signal PProg, and a drain connected to the write bit line WBT.

The WBT set voltage supply unit comprises: a PMOS transistor STP1 having a source connected to the boosted power supply Vpp and a gate supplied with an inverted signal of the storage data value Din;

a PMOS transistor STP2 having a source connected to a drain of the PMOS transistor STP1 and a gate supplied with the program pulse signal PProg; and

a PMOS transistor STP3 having a source connected to a drain of the PMOS transistor STP2, a gate supplied with a constant voltage VSetRef, and a drain connected to the write bit line WBT.

There is also provided an NMOS transistor DN1 which is connected between the WBT (a connection node of the drains of the PMOS transistors RTP2 and STP3 and the WBT) and the GND and has a gate supplied with the program pulse signal PProg.

The write bit line bar WBB are connected to a WBB reset voltage supply unit that comprises PMOS transistors RBP1 and RBP2 and a WBB set voltage supply unit that comprises PMOS transistors SBP1 to SBP3. More specifically, the WBB reset voltage supply unit comprises: a PMOS transistor RBP1 having a source connected to the boosted power supply Vpp and a gate supplied with an inverted signal of the storage data value Din (inverted by an inverter INV);

a PMOS transistor RBP2 having a source connected to a drain of the PMOS transistor RBP1, a gate supplied with the program pulse signal PProg, and a drain connected to the write bit line WBB. Further, the WBB set voltage supply unit comprises:

a PMOS transistor SBP1 having a source connected to the boosted power supply Vpp and a gate supplied with the storage data value Din;

a PMOS transistor SBP2 having a source connected to a drain of the PMOS transistor SBP1 and a gate supplied with the program pulse signal PProg; and

a PMOS transistor SBP3 having a source connected to a drain of the PMOS transistor SBP2, a gate supplied with the constant voltage VSetRef, and a drain connected to the write bit line WBT. and an NMOS transistor DN2 which is connected between the WBB (a connection node of the drains of the PMOS transistors RBP2 and SBP3 and the WBB) and the GND and has a gate supplied with the program pulse signal PProg.

The voltage VSetRef is at a constant level (constant voltage) and controls the set voltage applied to the write bit line pair WBT and WBB. When data is not written, the program pulse signal PProg always maintains at a high level to make PMOS transistors RTP2, STP2, RBP2, and SBP2 non-conductive, thereby preventing application of the voltage from the Vpp to the write bit lines WBT and WBB. Further, since both discharging transistors DN1 and DN2, which are connected to WBT and the WBB respectively, are made conductive to cause the WBT and the WBB to be fixed at a low level.

When low-level data, that is, data “0”, is supplied to the data signal Din, the Din is supplied to gates of the PMOS transistors RTP1 and SBP1 to make the transistors RTP1 and SBP1 both conductive. The inverted signal of the data signal Din is supplied to gates of the PMOS transistors STP1 and RBP1 to make the transistors STP1 and RBP1 non-conductive.

When the program pulse signal PProg changes from a high level to a low level, both the discharging transistors DN1 and DN2, connected to the write bit line pair WBT and WBB, respectively, are made non-conductive. When the low-level program pulse signal PProg is supplied to gates of the PMOS transistors RTP2, STP2, RBP2, and SBP2, all of the PMOS transistors RTP2, STP2, RBP2, and SBP2 are made conductive. Since the voltage path via the transistor STP1 is cut off, the voltage applied to the write bit line true WBT can be determined by subtracting two threshold voltages 2Vtp of transistors RTP1 and RTP2 from the voltage Vpp. That is, the voltage Vpp−2Vtp is applied to the write bit line WBT.

Since the voltage path via the transistor RBP1 is cut off, the voltage applied to the write bit line bar WBB can be determined by subtracting two threshold voltages 2Vtp of transistors SBP1 and SBP2 and a voltage across the current-controlled transistor SBP3 from the Vpp.

In the above case, the voltage at the write bit line true WBT is higher than the voltage at the write bit line bar WBB (WBT>WBB).

When high-level data, that is, data “1”, is supplied to the data signal Din, an inverted operation of the above operation is carried out. The voltages at the write bit line pairs WBT and WBB have a relationship WBT<WBB.

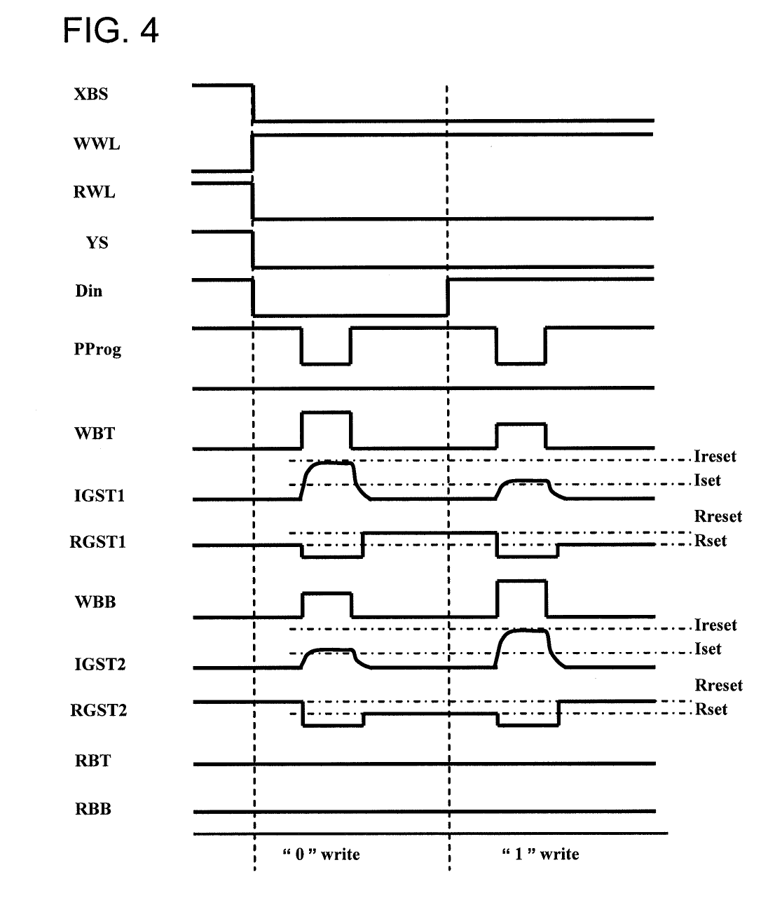

A write operation including the memory cell will be hereinafter described with reference to FIGS. 2 and 4.

When “0” writing is executed (“0” write), in the memory cell, as described above, the block selection signal XBS is set to a low level and the write word line WWL is set to a high level, while the RWL is set to a low level.

The input to the data signal Din is changed from a high level to a low level, and preparation for writing data “0” is initiated. Then, the program pulse signal PProg is changed from a high level to a low level. As described in the basic operation, while voltage pulses are supplied from the write circuit, and the voltage applied to the write bit line WBT is greater than the voltage applied to the write bit line WBB (WBT>WBB). These pulse-waveform voltages control the currents flowing through the driver transistors WN1 and WN2.

Currents IGST1 and IGST2 flow through the chalcogenide elements GST1 and GST2, respectively. The current values of IGST1 and IGST2 depend on the voltages at the write bit lines WBT and WBB and exhibit a relationship IGST1>IGST2. The chalcogenide elements GSTs are temporarily caused to be in a dynamic resistance state to generate heat.

Next, when the program pulse signal PProg is changed from a low level to a high level again, the voltage levels at the write bit lines WBT and WBB are lowered by the discharging transistors DN1 and DN2 to the GND level. Simultaneously, the currents IGST1 and IGST2 flowing through the chalcogenide elements GST1 and GST2 are cut off.

When the currents flowing through the chalcogenide elements GST are cut off, the chalcogenide element GST1, which has been generating large heat because of the large current (IGST1), stabilizes in a high-resistance amorphous state (Rreset).

On the other hand, the chalcogenide element GST2, which has been generating somewhat small heat because of the small current (IGST2), stabilizes in a low-resistance crystalline state (Rset).

Next, when data “1” is written (“1” write), pulse voltages having a relationship WBT<WBB are supplied from the write circuit, and current pulses IGST1 and IGST2 having a relationship IGST1<IGST2 flow through the chalcogenide elements GST1 and GST2, respectively. The chalcogenide elements GST1 and GST2 are programmed to have a resistance value of Rset and Rreset, respectively. In this way, complementary data can be written with a single program pulse.

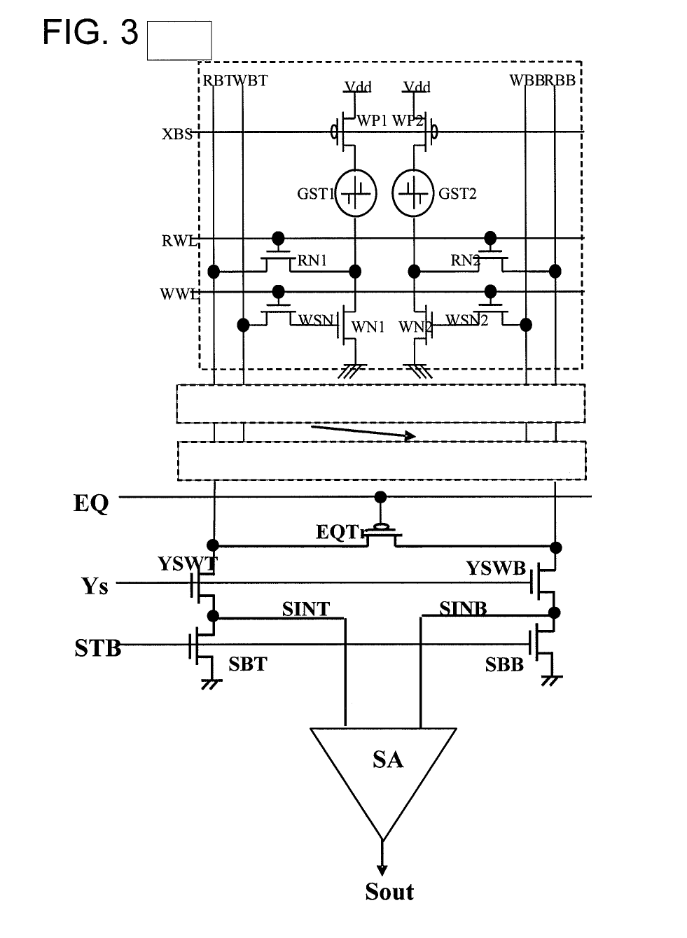

FIG. 3 shows an example of the configuration of a complementary memory cell and a read circuit according to the present exemplary embodiment. The read circuit shown in FIG. 3 comprises a Y switch YSWT having a drain connected to the read bit line RBT and a Y switch YSWB having a drain connected to the read bit line RBB. Both of the Y switches YSWT and YSWB have gates supplied with a bit line selection signal Ys in common. The read circuit further comprises a select transistor SBT having a drain connected to a source of the Y switch YSWT and a select transistor SBB having a drain connected to a source of the Y switch YSWB. Both of the select transistors SBT and SBB have gates supplied with a signal (strobe signal) STB that controls discharging of the bit line pair and sources connected to the GND. A connection node SINT of the Y switch YSWT, drains of the select transistor SBT and a connection node SINB of the Y switch YSWB and a drain of the select transistor SBB are connected to the differential input terminals of a differential sense amplifier SA. A PMOS transistor EQTr connected between the read bit line pair (RBT and RBB) and having a gate connected to an equalization signal EQ executes equalization of the read bit line pair (RBT and RBB).

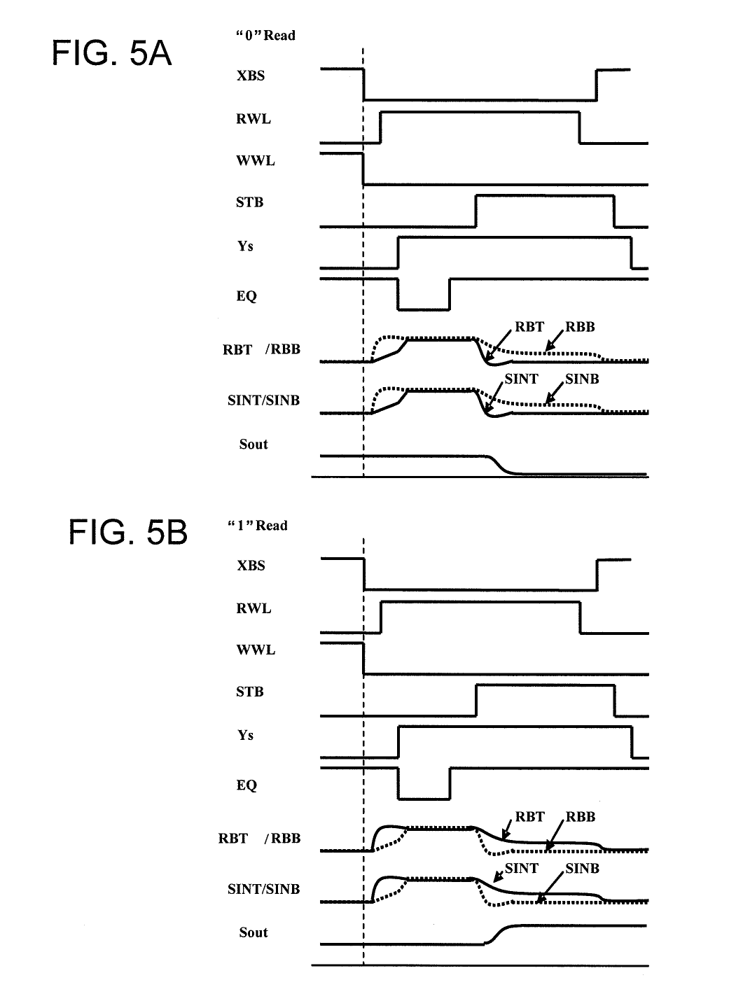

Next, an operation of reading data from the memory cell will be described with reference to FIG. 3 and FIGS. 5A and 5B.

FIG. 5A shows operation waveforms when reading data “0” (“0” read). According to the above write procedure, the chalcogenide elements GST1 and GST2 are now in a high-resistance state (Rreset) and a low-resistance state (Rset), respectively.

A signal Ys that activates Y switches YSWT and YSWB which transfer potentials of the read bit lines RBT and RBB to the differential sense amplifier SA maintains a low level.

Also, the read bit line pair RBT and RBB are disconnected, because of the PMOS transistor EQTr which receives the EQ signal.

The STB signal is at a low level, and the transistors SBB and SBT are made non-conductive.

When the block selection signal XBS and the write word line WWL are set to a low level and the read word line RWL is set to a high level, the read bit line true RBT is supplied with a potential obtained by subtracting the Rreset resistance of the chalcogenide element GST1 and the transistor RN1 from the Vdd level. In this example, since the resistance of the chalcogenide element GST1 is high, the potential of the read bit line true RBT is gradually raised from the GND level. On the other hand, the read bit line RBB having a complementary relationship with respect to the RBT is provided with a potential obtained by subtracting the Rset resistance of the chalcogenide element GST2 and the voltage across the transistor RN2, from the Vdd level. Since the resistance of the chalcogenide element GST2 is low, the potential of the read bit line RBB quickly rises via the memory cell.

Next, the Ys signal is set to a high level, and simultaneously, the EQ signal is set to a low level. As a result, the EQ signal is supplied to the gate of the PMOS transistor EQTr, and the read bit line pair RBT and RBB are electrically connected. Thus, the RBT and RBB are raised to the same level. When the potentials of the read bit line pair RBT and RBB reach the same level, the EQ signal is set to a high level, and the read bit line pair RBT and RBB are electrically disconnected.

Then, by switching the level of the STB signal from low to high, the potentials of the read bit line pair RBT and RBB are lowered toward the GND level.

Since the chalcogenide element GST1 has a high resistance, the read bit line RBT has a low current supply capability. Thus, the level of the read bit line RBT is rapidly discharged to the GND level. The signals SINT and SINB, which are connected to a pair of Y switches YSWT and YSWB, respectively, and supplied to the sense amplifier SA, transfer the potential changes of the RBT and the RBB to the sense amplifier SA.

The sense amplifier SA inverts the potential levels of the SINT and the SINB with a differential circuit to output a low level, that is, data “0”, at an output Sout.

FIG. 5B shows operation waveforms when reading data “1” (“1” read). Data “1” is read based on the principle opposite to that of reading data “0” and data “1” is output at the output Sout of the sense amplifier.

In the present exemplary embodiment, the currents IGST1 and IGST2 for programming which are supplied to the chalcogenide elements GSTs are not generated by the boosted power supply Vpp but supplied from the currents flowing from the power supply Vdd, without using an internal voltage-boost power supply. Thus, in the present exemplary embodiment, the programming does not affect the current efficiency. Further, in the present exemplary embodiment, since a current supplied from the internal voltage-boost power supply which is in charge of supplying voltages of word lines WBT and WBB is merely used for charging and discharging purposes, the internal voltage-boost power supply itself may be not different from a word-line-voltage-boost power supply and a current value generally used in memory products. Thus, in the present exemplary embodiment, an increase of current consumption in programming can be prevented.

According to the present exemplary embodiment, a high-speed write operation can be realized. This is because, in the present exemplary embodiment, the set programming and the reset programming are not controlled separately. Instead, based on a single pulse width (equal to a reset pulse width), the voltage supplied to the write word line is controlled and programming is thus executed.

Further, according to the present invention, since a cell is configured to have a complementary structure, changes in the voltage obtained from data written in a complementary manner can be quickly detected and amplified. Thus, with the present invention, even when the difference in resistance between two memory elements GSTs in a cell is decreased, high-speed access, stable detection of a differential voltage and decision of data are enabled.

While a cell array comprising a plurality of memory cells of FIG. 1, the write circuit of FIG. 2, and the read circuit of FIG. 3 have been described with separate drawings only for reasons of drawing simplicity, these elements are mounted on a single semiconductor chip (semiconductor device). The memory circuit and semiconductor device according to the present exemplary embodiment realize a reduction of current consumption, an expansion of operating margin, an increase of speed and are suitably mounted as a nonvolatile memory circuit and a nonvolatile memory device on various data processing equipment, communication equipment, and so forth.

In the exemplary embodiments, GST (GeSbTe) is used as a material for the phase-change memory element. However, needless to say, other phase-change materials may be used.

Unlike the above Patent Document 2, according to the present exemplary embodiment, memory elements GSTs in a cell are provided with bias voltages which are supplied by a biasing means and decreased in accordance with resistance of the memory elements, and a sense amplifier receives the bias voltages at the read bit lines RBT and RBB as differential inputs to detects potential changes. Thus, the present invention differs from the Patent Document 2 in the configuration and the read operation.

The disclosures of the Patent Documents 1 and 2 described above are incorporated herein by reference. Modifications and adjustments of the exemplary embodiment and an embodiment are possible within the scope of the overall disclosure (including claims) of the present invention, and based on the basic technical concept of the invention. Various combinations and selections of various disclosed elements are possible within the scope of the claims of the present invention. That is, the present invention of course includes various variations and modifications that could be made by those skilled in the art according to the overall disclosure including the claims and the technical concept.

What is claimed is:

1. A semiconductor device comprising:
first and second driver transistors; and
first and second phase-change memory elements arranged between a power supply and outputs of the first and second driver transistors, respectively,
one of the first and second driver transistors, in accordance with a value of write data, receiving a reset voltage at a control terminal thereof to cause a reset current to flow from a power supply through associated one of the first and second phase-change memory elements, while the other of the first and second driver transistors, in accordance with the value of the write data, receiving a set voltage at a control terminal thereof to cause a set current to flow from the power supply through the other of the first and second phase-change memory elements.

2. The semiconductor device according to claim 1, wherein voltages, which undergo respective voltage drops of predetermined voltage levels different each other from a boosted voltage which is higher than a voltage of the power supply, are produced as the reset and set voltages in a write circuit.

3. The semiconductor device according to claim 2, comprising
a first write switch arranged between a first write bit line of a complementary write bit line pair and the control terminal of the first driver transistor; and
a second write switch arranged between a second write bit line of the complementary write bit line pair and the control terminal of the second driver transistor, the first and second write switches connected in common to a write word line; wherein
the reset voltage and the set voltage generated in the write circuit are supplied to the complementary write bit line pair and then are applied to the control terminals of the one of the first and second driver transistors and the other of the one of the first and second driver transistors, respectively, via the first and second write switches made conductive when the write word line is activated.

4. The semiconductor device according to claim 1, comprising
a first read switch arranged between a first read bit line of a complementary read bit line pair and a first connection node of the first phase-change memory element and the first driver transistor;
a second read switch arranged between a second read bit line of the complementary read bit line pair and a second connection node of the second phase-change memory element and the second driver transistor, the first and second read switches being connected in common to a read word line; wherein
the first and second connection nodes are connected to the complementary read bit line pair via the first and second read switches made conductive when the read word line is activated.

5. The semiconductor device according to claim 1, comprising
first and second selection switches arranged between the power supply and the first and second phase-change memory elements, respectively, the first and second selection switches receiving a selection signal in common to be made conductive when the selection signal is activated.

6. A semiconductor device comprising:
a first select transistor having a gate that receives a selection signal and having a source connected to a power supply;
a first driver transistor having a source connected to a ground;
a first phase-change memory element connected between a drain of the first select transistor and a drain of the first driver transistor;
a second select transistor having a gate that receives the selection signal and having a source connected to the power supply;
a second driver transistor having a source connected to the ground;
a second phase-change memory element connected between a drain of the second select transistor and a drain of the second driver transistor;
a first write switch arranged between a gate of the first driver transistor and a first write bit line of a complementary write bit line pair, the first write switch being made conductive or non-conductive by a write word line;
a first read switch arranged between a first connection node of the first phase-change memory element and the first driver transistor and a first read bit line of a complementary read bit line pair, the first read switch being made conductive or non-conductive by a read word line;
a second write switch arranged between a gate of the second driver transistor and a second write bit line of the complementary write bit line pair, the second write switch being made conductive or non-conductive by the write word line; and
a second read switch arranged between a second connection node of the second phase-change memory element and the second driver transistor and a second read bit line of the complementary read bit line pair, the second read switch being made conductive or non-conductive by the read word line.

7. A semiconductor device comprising:
a plurality of memory cells, each memory cell as set forth in claim 1.

8. The semiconductor device according to claim 7, comprising
a write circuit that supplies the first and second driver transistors in the memory cell with voltages, which undergo respective voltage drops of predetermined voltage levels different each other from a boosted voltage which is higher than a voltage of the power supply, as the reset and set voltages.

9. A semiconductor device comprising:
a plurality of memory cells, each memory cell as set forth in claim 6; and
a write circuit supplying the set and reset voltages as complementary write voltages to the complementary write bit line pair,
wherein the write circuit controls to supply the set voltage and the reset voltage in a uniform period,
provides, in accordance with a value of write data, the complementary write bit line pair with voltages that undergo respective voltage drops of predetermined voltage levels different each other from a boosted voltage which is higher than a voltage of the power supply as the set voltage and the reset voltage, and
applies the set voltage and the reset voltage to gates of the first and second driver transistors of a selected memory cell from the complementary write bit line pair via the first and second write switches made conductive when the write word line is activated.

10. The semiconductor device according to claim 9, wherein the write circuit comprises:
a first reset voltage supply circuit comprising first and second transistors connected in series between a boosted potential terminal and a first write bit line of a complementary write bit line pair; and
a first set voltage supply circuit comprising third, fourth, and fifth transistors connected in series between the boosted potential terminal and the first write bit line;
wherein a data signal and an inverted signal of the data signal are supplied to gates of the first transistor and the third transistor of the first reset voltage supply circuit and the first set voltage supply circuit, respectively, a program pulse signal is commonly supplied to gates of the second transistor and the fourth transistor of the first reset voltage supply circuit and the first set voltage supply circuit, and a predetermined bias voltage is applied to a gate of the fifth transistor of the first set voltage supply circuit, and wherein the write circuit further comprises:
a second reset voltage supply circuit comprising sixth and seventh transistors connected in series between the boosted potential terminal and a second write bit line of the complementary write bit line pair; and
a second set voltage supply circuit comprising eighth, ninth, and tenth transistors connected in series between the boosted potential terminal and the second write bit line,
wherein the inverted signal of the data signal and the data signal are supplied to gates of the sixth transistor and the eighth transistor of the second reset voltage supply circuit and the second set voltage supply circuit, respectively, the program pulse signal is commonly supplied to gates of the seventh transistor and the ninth transistor of the second reset voltage supply circuit and the second set voltage supply circuit, and the predetermined bias voltage is applied to a gate of the tenth transistor of the second set voltage supply circuit.

11. The semiconductor device according to claim 9, comprising
first and second discharging transistors, through which currents flow when the program pulse signal is not activated, between the first and second write bit lines of the complementary write bit line pair and the ground.

12. The semiconductor device according to claim 9, comprising
a read circuit comprising:
a pair of Y switches, one of the Y switches being connected to the first read bit line of the complementary read bit line pair and the other switch connected to the second read bit line of the complementary read bit line pair, the pair of Y switches commonly made conductive or non-conductive by a column selection signal;
an equalization transistor arranged between the first and second read bit lines of the complementary read bit line pair to connect the first read bit line and second read bit line when an equalization signal is activated;
a pair of transistors arranged between the pair of Y switches and the ground and made conductive or non-conductive by a control signal supplied thereto; and
a sense amplifier receiving potentials of the first and second read bit lines differentially via the pair of Y switches made conductive by the column selection signal.
